(19) United States
(12) Patent Application Publication
(10) Pub. No.: US 2003/0082848 A1
(43) Pub. Date: May 1, 2003

(54) Semiconductor device and manufacturing method

(76) Inventor: Takayuki Ohuchida, Beppu-shi (JP)

Correspondence Address: TEXAS INSTRUMENTS INCORPORATED, P O BOX 655474, M/S 3999, DALLAS, TX, 75265

(21) Appl. No.: 10/279,686

(22) Filed: Oct. 24, 2002

(30) Foreign Application Priority Data
Oct. 25, 2001 (JP) 2001-327142

(51) Int. Cl. H01L 21/44

(52) U.S. Cl. 438/106

(57) ABSTRACT

A semiconductor device and its manufacturing method with which the conductive balls can be prevented from falling off. In terms of the configuration, semiconductor chip 100 is mounted onto the principal surface of insulated substrate 102, and solder balls 108 serving as external connection terminals are mounted on the rear surface. Insulated substrate 102 has via holes 112 to fill with solder paste for mounting solder balls 108. Via holes 112 contain internal channels 304 on inner peripheral surface 302 in order to exhaust the gas generated when the solder is melted to the outside.

### FIELD OF THE INVENTION

The present invention pertains to a semiconductor device and its manufacturing method.

### BACKGROUND OF THE INVENTION

In recent years, as electronic information equipment has become capable of higher performance levels, semiconductor packages have been expected to be increasingly miniaturized as the pin count is increased. Thus, a type of bonding called BGA which utilizes conductive balls (solder balls) to form external connection terminals is receiving attention.

FIG. 11 schematically shows the basic configuration of a popular BGA type semiconductor package. In said semiconductor package 160, semiconductor chip 1600 that is formed with an integrated circuit is fixed to insulated substrate 1602 via die paste 1604 and sealed with molding resin 1618. Semiconductor pattern 1606 is formed on the principal surface of insulated substrate 1602, and said semiconductor pattern 1606 is connected to electrode pad 1616 of semiconductor chip 1600 via semiconductor wire 1610. Solder balls (conductive balls) 1608 used as external connection terminals are attached to the rear surface of insulated substrate 1602. Via holes 1612 or through-holes are formed on insulated substrate 1602, and said via holes 1612 are filled with solder paste in order to connect semiconductor pattern 1606 to the spherical solder balls. The solder powder in the solder paste is melted in a reflow furnace to become integrated with the spherical solder balls 1608 to form external connection terminals.

Circuit board (or motherboard) 1620 on which semiconductor package 160 is mounted has connecting parts 1622 at the positions on semiconductor package 160 that correspond to solder balls 1608. Solder balls 1608 on semiconductor package 160 and connector parts 1622 of circuit board 1620 are joined together by soldering during a solder reflow step.

Incidentally, it is known that a phenomenon called ball-off occurs, that is, the falling off of solder balls 1608 from semiconductor package 160 during the mounting of semiconductor package 160 on circuit board 1620. As shown schematically in FIG. 12, ball-off occurs when the (SSF) force for the solder paste to form spheres with solder balls 108 is greater than the (SWF) force for the solder paste to adhere to semiconductor pattern 1606. In general, the larger the solder balls 1608 and the narrower and deeper the inner diameter of via holes 1612, the greater the likelihood that ball-off will occur. In particular, when the organic solvents in the solder paste vaporize to become gas G and said gas G remains at the contact interface with semiconductor pattern 1606, the contact area between the solder paste and semiconductor pattern 1606 becomes smaller. Thus, force SWF for the solder paste to adhere to semiconductor pattern 1606 decreases and ball-off is more likely to occur. Ball-off will result in poor conduction between semiconductor package 160 and circuit board 1620.

Furthermore, it is known that in order to increase force SWF for the solder to adhere to semiconductor pattern 1606, solder balls 1608 should be made smaller, and via holes 1612 should be made wider and less deep. However, there is the problem that when semiconductor package 160 is mounted on circuit board 1620, the positioning of solder balls 1608 with respect to connector parts 1622 becomes more difficult if solder balls 1608 are made smaller. In addition, it is difficult to increase the inner diameter of via holes 1612 due to the restricted pattern arrangement density on insulated substrate 1602, and it is difficult to make via holes 1612 shallower (since insulated substrate 1602 must become thinner) due to restrictions in terms of assuring the strength of insulated substrate 1602. Thus, the development of a technology which prevents the solder balls (conductive balls) from falling off without being subject to said difficulties is in great demand.

Therefore, the objective of the present invention is to present a semiconductor device and its manufacturing method with which the conductive balls can be prevented from falling off.

### SUMMARY OF THE INVENTION

In order to achieve the aforementioned objective, the semiconductor chip mounting substrate pertaining to the present invention is characterized in that it is a semiconductor device equipped with a semiconductor mounting substrate having a chip mounting area provided on the principal surface where a semiconductor chip is mounted, multiple via holes which pass from the aforementioned chip mounting area to the rear surface, and multiple semiconductor patterns provided on the aforementioned principal surface and equipped with wire connection lands electrically connected to the aforementioned semiconductor chip and connection pads formed at the positions corresponding to the aforementioned via holes, a semiconductor chip mounted in the aforementioned chip mounting area, conductive balls attached to the aforementioned via holes, and a sealant used to seal the aforementioned semiconductor chip, wherein the aforementioned via hole is provided with at least one internal channel which is formed away from the center of the aforementioned via hole toward the outside so that it passes from the aforementioned principal surface to the aforementioned rear surface.

With this configuration, gas that forms when the solder is melted can be evacuated to the outside via the internal channels of the via holes. Thus, the gas can be prevented from remaining at the interface between the solder in the via holes and the conductive pattern. As a result, a decrease in the adhesive ability of the solder in the via holes to the conductive pattern can be prevented, so that the conductive balls can be prevented from falling off.

In addition, in the present invention, it is desirable that the aforementioned internal channels pass through from the aforementioned principal surface to the aforementioned rear surface obliquely.

In addition, the present invention is characterized in that it is a semiconductor device equipped with a semiconductor mounting substrate having a chip mounting area provided on the principal surface where a semiconductor chip is mounted, multiple via holes which pass from the aforementioned chip mounting area to the rear surface, and multiple semiconductor patterns provided on the aforementioned principal surface and equipped with wire connection lands electrically connected to the aforementioned semiconductor chip and connection pads formed at the positions corresponding to the aforementioned via holes, a semiconductor chip mounted in the aforementioned chip mounting area, conductive balls attached to the aforementioned via holes, and a sealant used to seal the aforementioned semiconductor chip, wherein the aforementioned via hole is provided with at least one convex part which is formed facing the center of the aforementioned via hole and passes from the aforementioned principal surface to the aforementioned rear surface.

In addition, the present invention is characterized in that it involves a step in which the aforementioned semiconductor chip mounting substrate is prepared, a step in which the semiconductor chip is mounted in the aforementioned chip mounting area, a step in which the aforementioned semiconductor chip and the aforementioned wire connection lands are connected using semiconductor wires, a step in which the conductive balls are formed at the aforementioned via holes, and a step in which the aforementioned semiconductor chip is sealed using a sealant.

### BRIEF DESCRIPTION OF THE DRAWINGS

FIG. 1 is a partial cutaway oblique view showing the configuration of the semiconductor package pertaining to the first embodiment of the present invention.

FIG. 2 is a cross section showing the cross sectional structure of the semiconductor package shown in FIG. 1.

FIG. 3(A) is a bottom view of a via hole formed on the semiconductor package shown in FIG. 1 when viewed from the rear surface side of the insulated substrate.

FIG. 3(B) is a cross section thereof.

FIGS. 4(A)-4(G) are cross sections for explaining each manufacturing step of the semiconductor package shown in FIG. 1.

FIGS. 5(A)-5(C) are cross sections of solder ball attachment steps during the manufacturing process shown in FIG. 4.

FIG. 6 is an expanded cross section for explaining the function of the first embodiment.

FIG. 7(A) is a bottom view of the via holes pertaining to the first embodiment variant and FIG. 7(B) is the second embodiment variant of the first embodiment when viewed from the rear surface side of the insulated substrate.

FIGS. 8(A)-8(C) are bottom views of the via holes pertaining to the third embodiment variant (A), the fourth embodiment variant (B), and the fifth embodiment variant (C) of the first embodiment when viewed from the rear surface side of the insulated substrate.

FIG. 9(A) is a bottom view of the via holes pertaining to the sixth embodiment variant and FIG. 9(B) is the seventh embodiment variant (B) of the first embodiment when viewed from the rear surface side of the insulated substrate.

FIG. 10(A) is a bottom view of the via hole pertaining to the eighth embodiment variant of the first embodiment when viewed from the rear surface side of the insulated substrate and FIG. 10(B) is a cross section thereof.

FIG. 11 is a cross section showing the basic structure of a typical semiconductor package.

FIG. 12 is an expanded cross section for explaining the problems of the semiconductor package shown in FIG. 11.

### REFERENCE NUMERALS AND SYMBOLS AS SHOWN IN THE DRAWINGS

In the figures, 10 represents a semiconductor package, 100 a semiconductor chip, 102 an insulated substrate, 104 a chip mounting area and die paste, 106 a conductive pattern, 110 a conductive wire, 112 a via hole, 118 a sealant, 122 a connection pad, 200 a circuit board, 302, 702, 802, 812, 822 inner peripheral surfaces, 304, 704, 804, 1006 internal channels, 700, 710, 800, 810, 820, 900, 910, 1000 via holes, 804, 814, 824 convex parts, 1002 a cylindrical surface, and 1004 a tapered surface.

### DESCRIPTION OF THE EMBODIMENT

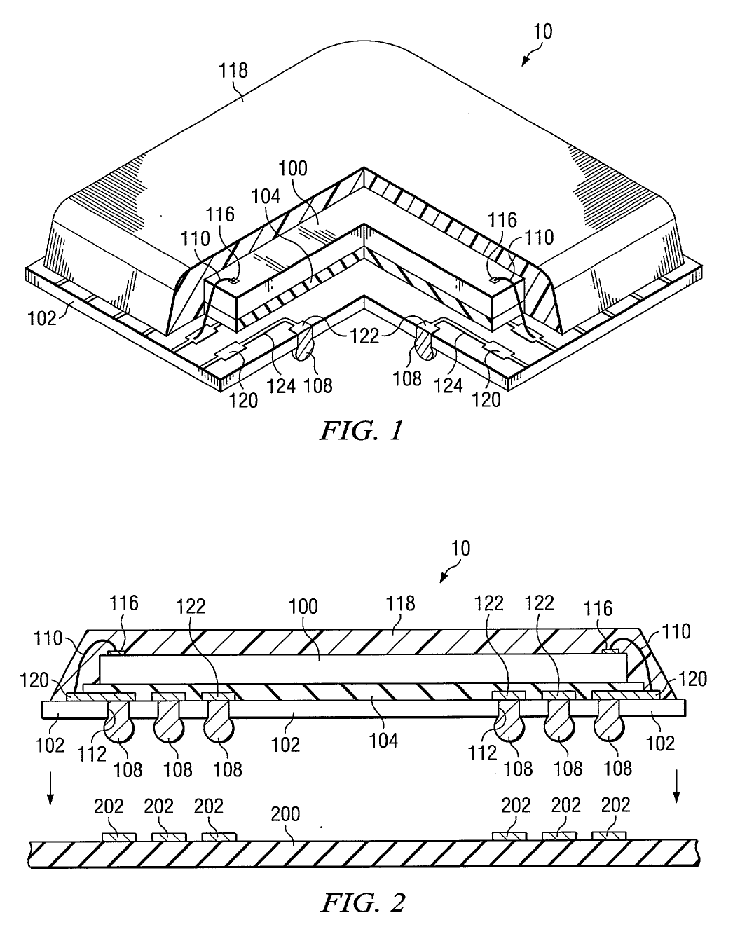

The present invention will be explained in detail based on an illustrated embodiment. FIG. 1 is a partial cutaway oblique view and FIG. 2 shows cross sections of the overall configuration of a semiconductor package to which the present invention is applied. As shown in FIG. 1, semiconductor chip 100 is fixed to insulated substrate 102 via a chip mounting area and die paste 104 and sealed using sealant 118 for semiconductor package 10 of the present embodiment. An integrated circuit (not illustrated) is formed on one side (upper plane in the figure) of a silicon substrate for semiconductor chip 100. Many electrode pads 116 led out from said integrated circuit are arranged at the periphery of semiconductor chip 100 on the side of the integrated circuit.

Insulated substrate 102 is a substrate made of polyimide or a ceramic. A conductive pattern made of copper is formed on the principal surface (surface on the side of semiconductor chip 100) of insulated substrate 102, and solder balls (conductive balls) 108 serving as external connection terminals are provided on the rear surface of insulated substrate 102. The conductive pattern includes wire connection lands 120 to be connected to electrode pads 116 of semiconductor chip 100 via conductive wires 110, connection pads 122 to be connected to solder balls 108 through via holes 112 (to be described below), and lead parts 124 for connecting these wire connection lands 120 to connection pads 122. Wire connection lands 120 are arranged along the periphery of semiconductor chip 100 to be mounted onto insulated substrate 102, and connection pads 122 are arranged in the inner area of insulated substrate 102.

Solder balls 108 are spheres having a diameter of approximately 0.25 mm and are made of an alloy containing tin (Sn) and lead (Pb), for example. As shown in FIG. 2, solder balls 108 are to be connected to connection terminals 202 of circuit board 200 during the mounting of semiconductor package 10 onto circuit board 200 serving as a motherboard. Via holes 112 as through-holes are formed on insulated substrate 102 in order to connect connection pads 122 to solder balls 108. After a solder paste, that is, a conductive paste made of the mixture of solder powder and flux, is applied into said via holes 112 by means of a squeegee coating method during the manufacturing process in order to join connection pads 122 to the spherical solder balls, the balls are melted in a reflow furnace to fuse the solder powder in the conductive paste and in the solder balls 108 to form a single body in order to form the desired final shape to serve as the external connection terminals.

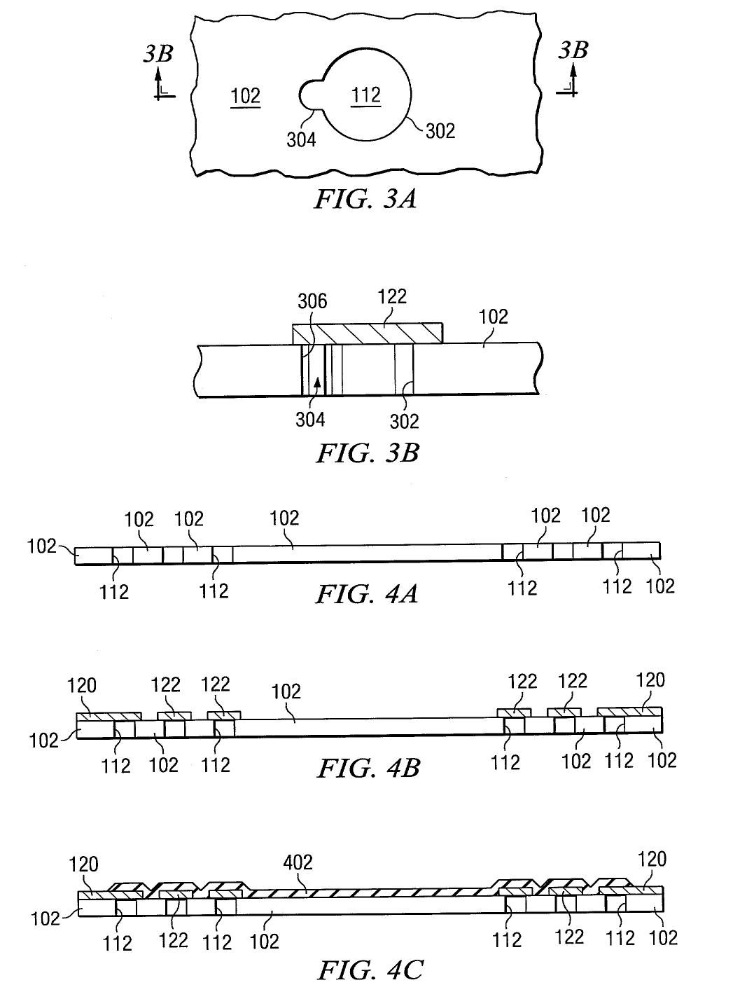

FIG. 3 (A) is a diagram showing the shape of insulated substrate 102 containing via holes 112 shown in FIG. 2 when viewed from the rear surface side. FIG. 3 (B) is a diagram showing a cross section along line III-III in FIG. 3 (A). As shown in FIG. 3 (A) and (B), via hole 112 is a through-hole with a quasi-circular cross section, and its inner diameter is approximately 0.2 mm, for example. Said via hole 112 has a somewhat cylindrical inner peripheral surface 302 and internal channel 304 allows said inner peripheral surface 302 to communicate with the outside. Said internal channel 304 extends from the principal surface of insulated substrate 102 to the rear surface in the direction via hole 112. The solder paste, which acts as conductive paste, fills via hole 112, including internal channel 304, and the solder in via hole 112 melted in the reflow furnace comes in contact with inner peripheral surface 302, but does not enter internal channel 304 due to the surface tension of the melted solder. The surface of connection pad 122 in internal channel 304 is covered with a thin film of solder as the solder liquefies. Said internal channel 304 allows the solder paste to communicate with the outside air when the solder melts during the mounting of semiconductor package 10 onto circuit board 200 and allows the volatile gases generated from the organic solvent contained in the solder paste to pass to the outside.

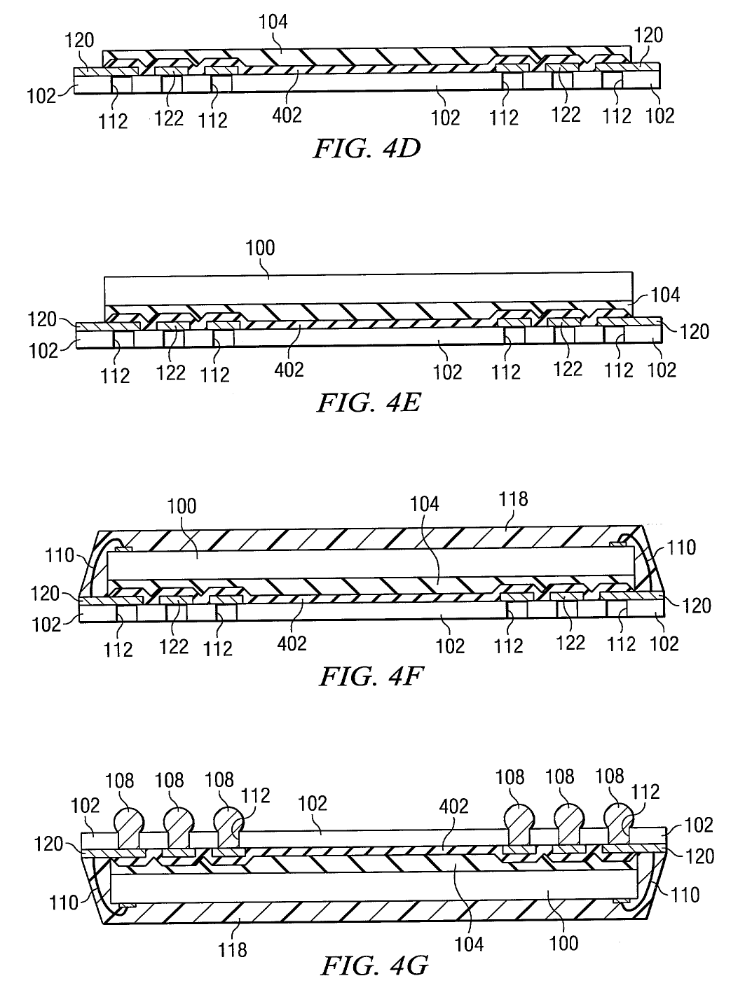

Next, a method for manufacturing semiconductor package 10 pertaining to the present embodiment will be explained with reference to FIG. 4. First, as shown in FIG. 4 (A), via holes 112, each having an internal channel 304 (FIG. 3), are formed on insulated substrate 102 made of polyimide or ceramics. Said via holes 112 are formed by means of a photolithographic technique, laser machining, or punching.

Then, after a copper foil is laminated over the entire surface of insulated substrate 102 on which via holes 112 are formed, etching is applied using a photolithographic technique in order to form the conductive pattern (that is, wire connection lands 120 and connection pads 122) shown in FIG. 4 (B). Then, as shown in FIG. 4 (C), the parts to be made into wire connection lands 120 are exposed on the principal surface of insulated substrate 102, solder mask 402 is coated, and nickel or gold plating is applied to exposed wire connection lands 120. As shown in FIG. 4 (D), die paste 104 made of an epoxy resin is applied to the chip mounting area of insulated substrate 102. As shown in FIG. 4 (E), semiconductor chip 100 formed through a different process is pressed from above onto liquid die paste 104 at a fixed pressure before it cures in order to spread die paste 104 over the entire lower surface of semiconductor chip 100. Under said conditions, the ambient temperature is raised with a heater to cure die paste 104 in order to fix semiconductor chip 100 to insulated substrate 102. Next, as shown in FIG. 4 (F), the electrode pads and wire connection lands 120 of semiconductor chip 100 are bonded together using conductive wires 110. After the bonding is completed, semiconductor chip 100 is sealed using sealant 118 made of a molding resin.

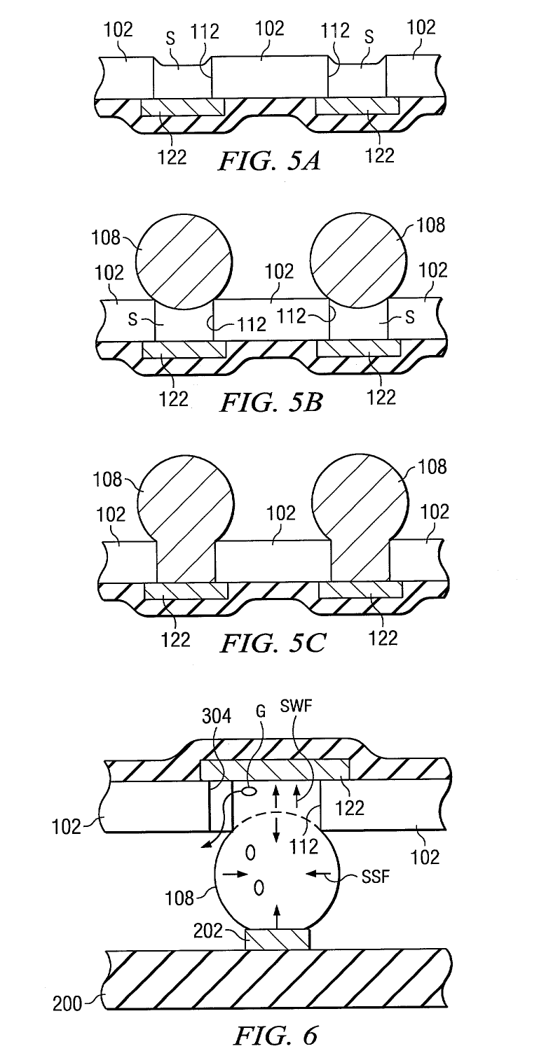

After semiconductor chip 100 is sealed, as shown in FIG. 4 (G), solder balls 108 are attached in via holes 112 of insulated substrate 102. That is, as shown in FIG. 5 (A), insulated substrate 102 is placed with its back place facing up, and solder paste S is filled into said via holes 112 using a squeegee (not shown). Then, as shown in FIG. 5 (B), solder balls 108 are brought into contact with solder paste S in via holes 112 and heated to a temperature of approximately 220° C.-250° C. As a result, solder balls 108 and solder paste S are fused as shown in FIG. 5 (C). The semiconductor package is completed through the aforementioned steps.

After semiconductor package 10 is completed, said semiconductor package 10 is mounted onto circuit board 200 shown in FIG. 2. That is, a paste (not shown) is preapplied to connection terminals 202 of circuit board 200, and solder balls 108 of semiconductor package 10 are brought into contact with said connection terminals 202 and heated to a temperature of approximately 220° C.-250° C. As a result, solder balls 108 of semiconductor package 10 and connection terminals 202 of circuit board 200 are connected together.

As shown in the expanded view in FIG. 6, during this process, gas G is generated as the organic solvent that is contained in the solder paste (not shown) which is applied to connection terminals 202 of circuit board 200 is vaporized. Because the solder does not enter internal channels 304 due to its inherent surface tension when the solder balls are melted, the gas G can escape to the outside through internal channels 304. Thus, the gas G is never present at the interface between the solder in via holes 112 and connection pads 122. Therefore, the contact area between the solder in via holes 112 and connection pads 122 is never diminished by the presence of gas G, so that adhesion force SWF of the solder in via holes 112 to connection pads 122 as it liquefies can be kept sufficiently strong. As a result, solder balls 108 can be prevented from falling off insulated substrate 102 during the step in which semiconductor package 10 is mounted onto circuit board 200.

As explained above, in the present embodiment, because via holes 112 are each provided with internal channels 304, the gas generated in the solder paste can be evacuated through internal channels 304 during the mounting of semiconductor package 10 onto circuit board 200, so that the gas can be prevented from remaining at the interface between the solder in via holes 112 and connection pads 122. As a result, solder balls 108 can be reliably prevented from falling off.

In particular, because internal channels 304 are formed on the inner peripheral surface of via holes 112, there is an area which communicates with the outside air when the solder is melted that can be formed using a simple configuration by exploiting the fact that the melted solder does not enter internal channels 304 due to its surface tension.

Furthermore, because via holes 112 are formed by means of a photolithographic technique, laser machining, or punching, so that via holes 112 with internal channels 304 can be formed easily.

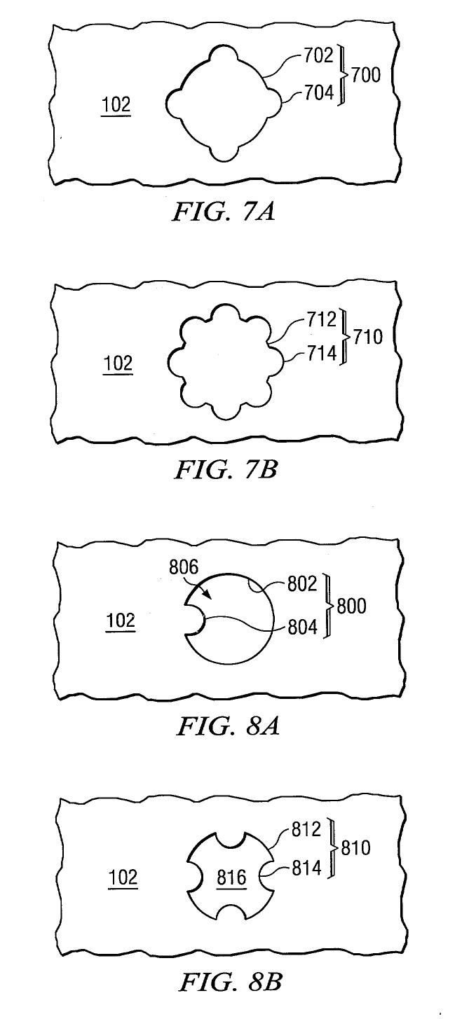

Next, embodiment variants of the present embodiment will be explained. FIG. 7 (A) and FIG. 7 (B) are diagrams showing the shapes of the via holes pertaining to a first and second embodiment variants when viewed from the rear side of insulated substrate 102. As shown in FIG. 7 (A), in via hole 700 pertaining to the first embodiment variant, four internal channels 704 are formed on inner peripheral surface 702 having a quasi-cylindrical shape. Internal channels 704 are arranged uniformly in the circumferential direction of inner peripheral surface 702, and each passes from the principal surface to the rear surface of insulated substrate 102. The solder paste does enter into the four internal channels 704 due to its surface tension when it is melted in the reflow furnace and fuses with the solder balls into its final shape after it is applied to via hole 700 using the squeegee coating method. These four internal channels 704 allow the melted solder paste to communicate with the outside air when the solder is melted during the step in which the semiconductor package is mounted onto the circuit board.

As shown in FIG. 7 (B), in via hole 710 pertaining to the second embodiment variant, eight internal channels 714 are formed on inner peripheral surface 712 having a quasi-cylindrical shape. Internal channels 714 are arranged uniformly in the circumferential direction of inner peripheral surface 712, and each extends from the principal surface to the rear surface of insulated substrate 102. The solder paste does not enter the eight internal channels 714 due to its surface tension when it is melted in the reflow furnace and fused with the solder balls to the final shape after it is loaded into via hole 710 using the squeegee coating method. These eight internal channels 714 allow the melted solder paste to communicate with the outside air when the solder is melted during the step in which the semiconductor package is mounted onto the circuit board.

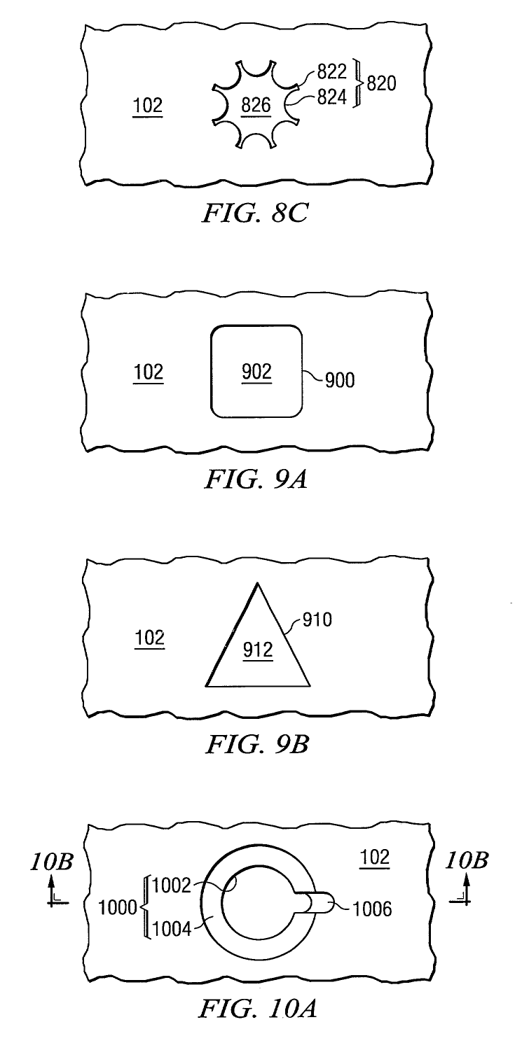

FIG. 8 (A) through (C) are diagrams showing the shapes of the via holes pertaining to third through fifth embodiment variants of the aforementioned embodiment when viewed from the back of insulated substrate 102. As shown in FIG. 8 (A), via hole 800 pertaining to the third embodiment variant has quasi-cylindrical inner peripheral surface 802 and convex part 804 protruding from said inner peripheral surface 802. Convex part 804 has a quasi-circular cross section and extends from the principal surface to the rear surface of insulated substrate 102. The solder paste from convex part 804 does enter area 806 in the region adjacent to convex part 804 and inner peripheral surface 802 due to the surface tension of the solder paste when it is melted in the reflow furnace and fused with the solder balls to the final shape after it is loaded into via hole 800 using the squeegee coating method. That is, said area 806 allows the melted solder paste to communicate with the outside air when the solder is melted during the step in which the semiconductor package is mounted onto the circuit board.

As shown in FIG. 8 (B), via hole 810 pertaining to the fourth embodiment variant has cylindrical inner peripheral surface 812 and 4 convex parts 814 protruding from said inner peripheral surface 812. Convex parts 814 are arranged uniformly in the circumferential direction of inner peripheral surface 812, and each extends from the principal surface to the rear surface of insulated substrate 102. The solder paste attempts to maintain the quasi-cylindrical shape while remaining in contact with 4 convex parts 814 and does not enter area 816 near inner peripheral surface 812 due to its surface tension when it is melted in the reflow furnace and fused with the solder balls to the final shape after it is loaded into via hole 810 using the squeegee coating method. That is, area 816 next to inner peripheral surface 812 of via hole 810 allows the melted solder paste to communicate with the outside air when the solder is melted during the step in which the semiconductor package is mounted onto the circuit board.

As shown in FIG. 8 (C), via hole 820 pertaining to the fifth embodiment variant has cylindrical inner peripheral surface 822 and 8 convex parts 824 protruding from said inner peripheral surface 822. Convex parts 824 are arranged uniformly in the circumferential direction of inner peripheral surface 822, each passing from the principal surface to the rear surface of insulated substrate 102. The solder paste attempts to maintain the quasi-cylindrical shape while remaining in contact with 8 convex parts 824 and does not enter area 826 near inner peripheral surface 822 due to its surface tension when it is melted in the reflow furnace and-fused with the solder balls to the final shape after it is loaded into via hole 820 using the squeegee coating method. That is, area 826 next to inner peripheral surface 822 of via hole 820 allows the melted solder paste to communicate with the outside air when the solder is melted during the step in which the semiconductor package is mounted onto the circuit board.

FIG. 9 (A) and (B) are diagrams showing the shapes of the via holes pertaining to sixth and seventh embodiment variants of the aforementioned embodiment when viewed from the back of insulated substrate 102. As shown in FIG. 9 (A), via hole 900 pertaining to the sixth embodiment variant has an approximately square cross section. Because the solder paste attempts to maintain a quasi-cylindrical shape while remaining in contact with the inner peripheral surface of via hole 900 due to its surface tension when it is melted in the reflow furnace and fused with the solder balls after it is loaded into via hole 900 using the squeegee coating method, areas 902 where the solder paste does not enter are formed at the four corners of via hole 900. Said areas 902 allow the melted solder paste to communicate with the outside air when the solder is melted during the step in which the semiconductor package is mounted onto the circuit board.

As shown in FIG. 9 (B), via hole 910 pertaining to the seventh embodiment variant has a quasi-triangular cross section. Because the solder paste attempts to maintain the quasi-triangular shape while remaining in contact with the inner peripheral surface of via hole 910 due to its surface tension when it is melted in the reflow furnace and fused with the solder balls to the final shape after it is loaded into via hole 910 using the squeegee coating method, areas 912 where the solder paste does not enter into are formed at the three corners of via hole 910. Said areas 912 allow the melted solder paste to communicate with the outside air when the solder is melted during the step in which the semiconductor package is mounted onto the circuit board.

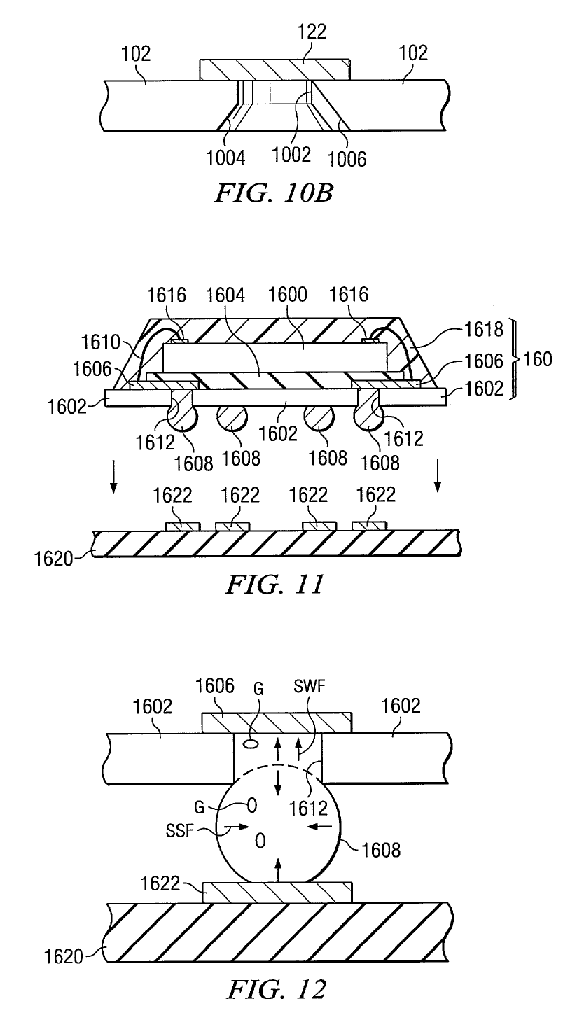

FIG. 10 (A) is a diagram showing the shape of the via hole pertaining to an eighth embodiment variant of the aforementioned embodiment when viewed from the back of insulated substrate 102. FIG. 10 (B) is a cross section along line X-X in FIG. 10 (A). Via hole 1000 shown in FIG. 10 (A) has cylindrical surface 1002 on the principal surface and tapered surface 1004 on the rear surface. Said tapered surface 1004 slopes in such a manner that the inner diameter of via hole 1000 increases toward the side of the rear surface. Furthermore, oblique internal channel 1006 is formed on tapered surface 1004 of via hole 1000. Said internal channel 1006 extends obliquely from the principal surface to the rear surface of insulated substrate 102 along tapered surface 1004. In the present embodiment variant, when the solder paste is melted in the reflow furnace and fused with the solder balls to the final shape after it is loaded into internal channel 1006 and via hole 1000 using the squeegee coating method, and when the completed semiconductor package 10 is mounted onto circuit board 200, the gas present at the interface between the solder in via hole 1000 and connection pad 122 can be evacuated through internal channel 1006, in order to prevent the solder ball from falling off.

An embodiment of the present invention was explained above using the figures. However, the present invention is not limited to the elements shown in the aforementioned embodiment, and it is clear that it can be modified on the basis of the descriptions in the claims.

As described above, in the present invention, because the gas generated from the conductive paste as the solder melts can be evacuated to the outside during the mounting process of the semiconductor package onto the circuit board, the gas can be prevented from remaining at the interface between the solder in the via holes and the conductive pattern, so that the conductive balls can be prevented from falling off.

1. Semiconductor device characterized in that it is equipped with
a semiconductor mounting substrate comprising
a chip mounting area provided on the principal surface where a semiconductor chip is mounted,
multiple via holes which pass from the aforementioned chip mounting area to the rear surface, and
multiple semiconductor patterns provided on the aforementioned principal surface and equipped with wire connection lands electrically connected to the aforementioned semiconductor chip and connection pads formed at the positions corresponding to the aforementioned via holes,
a semiconductor chip mounted in the aforementioned chip mounting area,
conductive balls attached to the aforementioned via holes, and
a sealant used to seal the aforementioned semiconductor chip,
wherein the aforementioned via holes are provided with at least one internal channel which is formed away from the center of the aforementioned via hole toward the outside so that it passes from the aforementioned main place to the aforementioned rear surface.

2. Semiconductor device of claim 1, characterized in that
the aforementioned internal channels pass from the aforementioned principal surface to the aforementioned rear surface obliquely.

3. Semiconductor device characterized in that it is equipped with
a semiconductor mounting substrate comprising
a chip mounting area provided on the principal surface where a semiconductor chip is mounted,
multiple via holes which pass from the aforementioned chip mounting area to the rear surface, and
multiple semiconductor patterns provided on the aforementioned principal surface and equipped with wire connection lands electrically connected to the aforementioned semiconductor chip and connection pads formed at the positions corresponding to the aforementioned via holes,
a semiconductor chip mounted in the aforementioned chip mounting area,
conductive balls attached to the aforementioned via holes, and
a sealant used to seal the aforementioned semiconductor chip,
wherein the aforementioned via hole is provided with at least one convex part which is formed away from the center of the aforementioned via hole and passing through the aforementioned principal surface to the aforementioned rear surface.

4. Manufacturing method for the semiconductor device of claims 1-3, characterized in that it includes
a step in which the aforementioned semiconductor chip mounting substrate is prepared,
a step in which the semiconductor chip is mounted onto the aforementioned chip mounting area,
a step in which the aforementioned semiconductor chip and the aforementioned wire connection lands are connected using semiconductor wires,
a step in which the conductive balls are formed at the aforementioned via holes, and
a step in which the aforementioned semiconductor chip is sealed using a sealant.
